(19) United States
(12) Patent Application Publication
(10) Pub. No.: US 2025/0212460 A1
(43) Pub. Date: Jun. 26, 2025

(54) NANOSHEET GATE-ALL-AROUND TRANSISTOR AND METHOD OF MANUFACTURING NANOSHEET GATE-ALL-AROUND TRANSISTOR

(71) Applicant: INSTITUTE OF MICROELECTRONICS, CHINESE ACADEMY OF SCIENCES, Beijing (CN)

(72) Inventors: Junfeng LI, Beijing (CN); Peng WANG, Beijing (CN); Guanqiao SANG, Beijing (CN); Renjie JIANG, Beijing (CN); Hang ZHANG, Beijing (CN); Qingzhu ZHANG, Beijing (CN); Huaxiang YIN, Beijing (CN); Jun LUO, Beijing (CN)

(21) Appl. No.: 18/894,146

(22) Filed: Sep. 24, 2024

(30) Foreign Application Priority Data
Dec. 22, 2023 (CN) 202311786481.9

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 62/151; H10D 64/017; H10D 84/0128; H10D 84/0135; H10D 84/038; H10D 84/83

(57) ABSTRACT

The present disclosure relates to a nanosheet gate-all-around transistor and a method of manufacturing a nanosheet gate-all-around transistor. The nanosheet gate-all-around transistor includes: a substrate having a shallow trench isolation structure on a surface of the substrate; a nanosheet stacking portion provided above the substrate, where the nanosheet stacking portion includes a stack formed by a plurality of nanosheets, the stack formed by the nanosheets constitutes a plurality of conductive channels, and the nanosheets are graphene nanosheets; a gate-all-around surrounding the nanosheet stacking portion; and a source/drain region located on two opposite sides of the nanosheet stacking portion, where a spacer is provided between the source/drain region and the gate-all-around.

### CROSS REFERENCE TO RELATED APPLICATION

This application claims priority to Chinese Patent Application No. 202311786481.9, filed on Dec. 22, 2023, the entire content of which is incorporated herein in its entirety by reference.

### TECHNICAL FIELD

The present disclosure relates to the field of transistors, in particular to a nanosheet gate-all-around transistor and a method of manufacturing a nanosheet gate-all-around transistor.

### BACKGROUND

With the technology node reduced to 3 nm, the problems faced by FinFET devices, such as short channel effect, device performance degradation and process reliability degradation, become noticeable. The vertically stacked nanosheet gate-all-around transistor (GAA-FET) is regarded as the most promising device structure.

In a traditional preparation process of the GAA-FET device, alternating stacked layers of SiGe and Si are often epitaxially grown, where Si is the final nanosheet channel (NS channel) and SiGe is a sacrificial layer. Due to the low carrier mobility and low thermal conductivity of Si, the electron transmission speed and the heat dissipation of the device are limited.

### SUMMARY

In a first aspect of the present disclosure, a nanosheet gate-all-around transistor is provided, including:
a substrate having a shallow trench isolation structure on a surface of the substrate;
a nanosheet stacking portion provided above the substrate, where the nanosheet stacking portion includes a stack formed by a plurality of nanosheets, the stack formed by the nanosheets constitutes a plurality of conductive channels, and the nanosheets are graphene nanosheets;
a gate-all-around surrounding the nanosheet stacking portion; and
a source/drain region located on two opposite sides of the nanosheet stacking portion, where a spacer is provided between the source/drain region and the gate-all-around.

Furthermore, the substrate is a silicon carbide substrate.

In a second aspect of the present disclosure, a method of manufacturing a nanosheet gate-all-around transistor is provided, including:
providing a substrate;
forming a silicon layer, including: forming the silicon layer on a surface of the substrate;
forming a graphene layer, including: forming a silicon carbide layer on the silicon layer, and evaporating a silicon atom in the silicon carbide layer by using a thermal decomposition method, so as to form the graphene layer;
repeating the forming a silicon layer and the forming a graphene layer, so as to form a stack in which the silicon layer and the graphene layer are alternately stacked;
etching the stack and the substrate with a partial thickness to form a fin;
forming a first dielectric layer on the substrate as a shallow trench isolation layer between fins;
forming a dummy gate on the fin, and forming a first spacer on a sidewall of the dummy gate;
etching the stack in the fin, so as to release a trench for forming a source/drain;
forming a second spacer on a sidewall of the stack in the fin;
epitaxially growing a semiconductor material in the trench, so as to form the source/drain;
removing the dummy gate;
etching off the silicon layer in the stack, so as to release a nanosheet channel, where a stack formed by the nanosheets constitutes a plurality of conductive channels; and
forming a gate-all-around to surround the stack formed by the nanosheets.

Furthermore, the substrate is a silicon carbide substrate.

Furthermore, a heating temperature of the thermal decomposition method is in a range of 1200° C. to 1400° C.

Furthermore, the heating temperature of the thermal decomposition method is in a range of 1300° C. to 1400° C.

Furthermore, the silicon layer in the stack is etched off by using a TMAH solution.

Furthermore, the first spacer is made of silicon nitride, and/or the second spacer is made of silicon nitride.

Furthermore, the silicon layer is formed by using a molecular beam epitaxy method.

Furthermore, the method further includes: after forming the gate-all-around, depositing an interlayer dielectric and performing interconnection.

### BRIEF DESCRIPTION OF THE DRAWINGS

Various other advantages and benefits will become clear to those ordinary skilled in the art by reading the detailed description of the preferred embodiments below. The drawings are only for the purpose of illustrating the preferred embodiments, and are not considered as limitation of the present disclosure.

FIG. 1 is a schematic diagram of a structure of a nanosheet gate-all-around transistor provided by the present disclosure.

FIG. 2 is a schematic diagram of a structure after forming a stack of a silicon layer and a graphene layer in a manufacturing method provided by the present disclosure.

### DETAILED DESCRIPTION OF EMBODIMENTS

Hereinafter, embodiments of the present disclosure will be described with reference to the drawings. However, it should be understood that these descriptions are only exemplary and are not intended to limit the scope of the present disclosure. In addition, in the following illustration, descriptions of well-known structures and technologies are omitted to avoid unnecessarily confusing the concepts of the present disclosure.

Various structural schematic diagrams according to the embodiments of the present disclosure are shown in the drawings. These drawings are not drawn to scale, in which some details are enlarged and some details may be omitted for the purpose of clear expression. The shapes, the relative sizes and the positional relationships of various regions and layers shown in the drawings are only exemplary, and may actually be deviated due to manufacturing tolerances or technical limitations. Moreover, those skilled in the art may additionally design regions/layers with different shapes, sizes and relative positions according to actual needs.

In the context of the present disclosure, when a layer/element is described to be “on” a further layer/element, the layer/element may be directly on the further layer/element, or there may be an intermediate layer/element therebetween. In addition, if a layer/element is “on” a further layer/element in one orientation, the layer/element may be “below” the further layer/element when the orientation is reversed.

In a traditional GAA-FET device, there are problems such as low carrier mobility and poor thermal conductivity when silicon is used as a nanosheet channel. Graphene is a two-dimensional single carbon atom layer material, in which carbon atoms form a crystal structure in the form of a two-dimensional honeycomb or a hexagonal lattice. Graphene has extremely high conductive carrier mobility, which is 100 times higher than that of silicon. Therefore, graphene is very suitable as a channel of a field effect transistor.

A main objective of the present disclosure is to provide a nanosheet gate-all-around transistor and a method of manufacturing a nanosheet gate-all-around transistor, so as to solve the problems of low carrier mobility and low thermal conductivity of a silicon nanosheet channel.

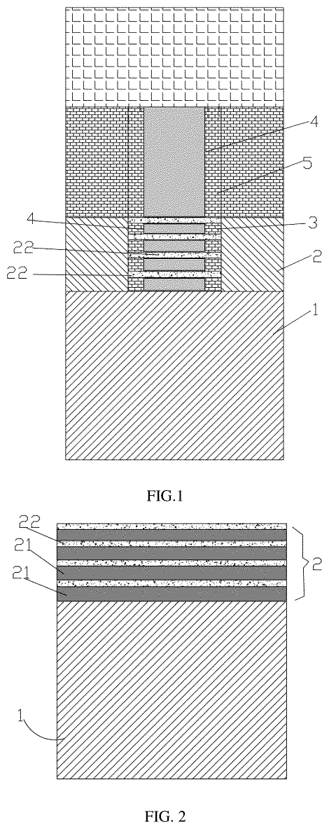

The present disclosure proposes a nanosheet gate-all-around transistor as shown in FIG. 1, including:
a substrate 1 having a shallow trench isolation structure on a surface of the substrate 1;
a nanosheet stacking portion provided above the substrate 1, where the nanosheet stacking portion includes a stack formed by a plurality of nanosheets, the stack formed by the nanosheets constitutes a plurality of conductive channels, and the nanosheets are graphene layers 22;
a gate-all-around 4 surrounding the nanosheet stacking portion; and
a source/drain region 2 located on two opposite sides of the nanosheet stacking portion, where a spacer is provided between the source/drain region 2 and the gate-all-around. The spacer includes a first spacer 5 and a second spacer 3. The first spacer 5 is located on a sidewall of a peripheral gate, and the second spacer 3 is located on a sidewall of an interlayer gate (i.e. a gate filled between nanosheets).

In the nanosheet gate-all-around transistor shown in FIG. 1, the substrate 1 may be any substrate known to those skilled in the art for carrying elements of a semiconductor integrated circuit, such as silicon-on-insulator (SOI), bulk silicon, silicon carbide, germanium, silicon germanium, gallium arsenide or germanium-on-insulator. A corresponding top layer semiconductor material is silicon, germanium, silicon germanium, or gallium arsenide. The substrate may also be a stacked structure composed of a plurality of layers of semiconductor materials. In some embodiments, the substrate 1 is made of silicon carbide, which has a better thermal conductivity performance compared with a silicon substrate, thereby effectively improving the heat dissipation performance of the device. As shown in Table 1 below, there are obvious differences in the electron mobility, the hole mobility and the thermal conductivity among silicon, silicon carbide and graphene. Graphene has outstanding advantages in all performances, and silicon carbide has an outstanding advantage in the thermal conductivity.

TABLE 1

| | Electron mobility | Hole mobility | Thermal conductivity |
|---|---|---|---|
| Material | (cm²/VS) | (cm²/VS) | (W/mK) |
| Si | 1500 | 450 | 150 |
| Graphene | 20000 | 4000 | 5300 |
| SiC | 900 | 115 | 490 |

A shallow trench isolation (STI) structure may be made of a high-k dielectric material such as oxide and oxynitride, e.g. typically silicon oxide (SiO₂), silicon oxynitride, and silicon nitride (SiNₓ), preferably doped or undoped low-temperature oxide.

In order to facilitate encapsulating and protecting a circuit structure, a passivation layer may be further provided above the gate to surround and cover the gate-all-around. The passivation layer may be made of a high-k dielectric material such as oxide and oxynitride, e.g. typically silicon oxide (SiO₂), silicon oxynitride and silicon nitride (SiNₓ).

Meanwhile, the gate-all-around 4 may include an interlayer gate filled among the plurality of nanosheets and a peripheral gate surrounding the nanosheet stacking portion.

The spacers may be made of a same material or different materials, for example, they may be independently made of at least one of: SiNₓ, SiO₂, SiCN, SiCON, SiCOx and SiNOx.

The graphene layer 22 in the stacked nanosheet gate-all-around device above may have a width in a range of 5 nm to 50 nm and a thickness in a range of 3 nm to 20 nm, which has a high integration. The graphene layer 22 may be composed of a plurality of layers, including but not limited to 3 layers, 4 layers and 5 layers etc. Since graphene is a two-dimensional single carbon atom layer material, in which carbon atoms form a crystal structure in the form of a two-dimensional honeycomb or a hexagonal lattice, graphene has extremely high conductive carrier mobility, which is 100 times higher than that of silicon. Therefore, the electron transmission speed of the device may be greatly improved by using graphene as the nanosheet channel of the nanosheet gate-all-around transistor shown in FIG. 1.

In some embodiments, the gate-all-around 4 includes a gate dielectric layer and a metal gate layer. In some embodiments, an N-type work function metal layer/a P-type work function metal layer may be provided between the gate dielectric layer and the metal gate layer.

The problem in the preparation process of the nanosheet gate-all-around transistor shown in FIG. 1 lies in the difficulty in the preparation and transfer of graphene. In order to solve this problem, the present disclosure provides a preparation method as follows, and the specific processes are introduced in combination with FIG. 1 to FIG. 2.

First, a substrate is provided, and a shallow surface layer of the substrate may be doped.

Then, a stack 2 for forming a fin is grown. As shown in FIG. 2, a silicon layer 21 and a graphene layer 22 are alternately stacked on the substrate 1, where the graphene layer 22 is used as a final nanosheet channel, and the silicon layer 21 is used as a sacrificial layer. The process of forming graphene is divided into two steps: first, the silicon carbide layer is epitaxially grown, and then silicon atoms in the silicon carbide layer are evaporated using a thermal decomposition method at a temperature in a range of 1200° C. to 1400° C. At this time, the remaining carbon atoms in a high energy state will be rearranged through sp2 hybridization in the lowest energy state, so as to form the graphene layer. As for the silicon layer, Si is epitaxially grown on the prepared graphene using a molecular beam epitaxy (MBE) method. As an atomic level control may be achieved using the molecular beam epitaxy method, Si atoms may be accurately deposited on the surface of graphene to form a Si epitaxial layer with a high quality, thereby forming a Si/graphene stack 2 with a high quality. The alternating period of the graphene layer and the silicon layer in the stack 2 is arbitrary, for example, the period shown in the figure is 4, i.e., the stack 2 includes four silicon layers and four graphene layers.

Next, the stack and the substrate with a partial thickness are etched to form the fin. During etching, with the help of a functional layer, such as a hard mask and a barrier layer, a predetermined pattern may be obtained using a patterning transfer technology. Specifically, the etching process may be as follows: a layer of photoresist is coated on the surface of the stack, then a mask plate is provided above the photoresist, a part of the photoresist is removed through exposure and development to obtain a photolithography window, and finally a part of each sacrificial preparatory layer and a part of each channel preparatory layer on the substrate which are not covered by the photoresist are etched and removed through the photolithography window, so as to obtain the fin.

Subsequently, a dielectric layer is formed on the substrate as a shallow trench isolation (STI).

Next, a dummy gate is formed on the fin, and a material of the dummy gate may be polysilicon. Those skilled in the art may reasonably select the material (such as commonly used silicon) for forming the above dummy gate preparatory layer according to the related art, which will not be repeated here.

Afterwards, a first spacer is formed on a sidewall of the dummy gate. The first spacer refers to a spacer on both sides of the dummy gate and across the fin, which is used to protect the sacrificial layer from being laterally etched in the subsequent process. There are many forms of forming methods and structures of the first spacer, and the specific process steps and structures will not be described in detail here. The first spacer may be made of a material having a high etching selectivity relative to the superlattice stack, such as silicon nitride. The deposition method includes but is not limited to PECVD, ALCVD, etc.

Then, etching is performed for source/drain, i.e., the stack in the fin is etched, so as to release a trench for forming the source/drain. A plasma etching method may be used in this etching step. The plasma etching method has a good isotropic etching effect on both Si and graphene, and has a very high selectivity relative to both SiO₂ and SiNₓ. Therefore, it is easy to obtain a trench in a regular shape when the trench for forming the source/drain is released by the plasma etching method. The plasma source may be at least one of O₂ plasma and Ar plasma.

A second spacer is formed on a sidewall of the stack in the fin. In this step, graphene in the stack is usually etched first to form an inner spacer trench, and then a low-k dielectric material is deposited to fill the inner spacer trench, so as to form the second spacer. The second spacer may be made of a material having a high etching selectivity relative to the superlattice stack, such as silicon nitride. The deposition method includes but is not limited to PECVD, ALCVD, etc.

Next, a semiconductor material is epitaxially grown in the trench to form the source/drain. In this step, the doping type is determined according to the transistor type. The semiconductor material may be silicon, germanium silicon, etc., which is not limited in the present disclosure. In this step, the semiconductor material is epitaxially grown first, then doping is performed, and finally an annealing treatment is performed.

Subsequently, the dummy gate is removed. During removal of the dummy gate, a dielectric material is usually first deposited for planarization, so as to protect the source/drain, and then the dummy gate is removed through CMP, etching, etc.

Next, the silicon layer in the stack is etched off, so as to release the nanosheet channel, and the stack formed by the nanosheets constitutes a plurality of conductive channels. When the silicon layer is removed in this step, it is preferable to use the TMAH solution for etching in order to have a high etching selectivity. The TMAH solution is an alkaline solution composed of sodium tetramethylamino bromide (TMAH) and water, which has a good isotropic etching effect on silicon and a high selectivity for graphene and SiC.

Then, a gate-all-around is formed to surround the stack formed by the nanosheets. This step is usually divided into depositions of a plurality of layers, which may include a HK layer (high-k dielectric layer), an N-type work function metal layer and a metal gate layer.

Finally, an insulating dielectric material is further deposited to cover a functional circuit structure. Then, desired electrode leading out and interconnection processes, such as etching a plug in a contact hole, metallization interconnection, bonding pad, etc., are performed, which will not be described in detail in the present disclosure.

In summary, compared with the related art, the present disclosure achieves the following technical effects:
(1) Using graphene as the nanosheet channel may give full play to the advantages of high carrier mobility and good thermal conductivity performance, thereby improving the electron transmission rate of the transistor.
(2) The graphene layer is obtained by growing silicon carbide and then producing graphene through thermal decomposition, so that the problem of difficult preparation and transfer of graphene is solved.
(3) Silicon carbide is used as the substrate due to its high thermal conductivity, thereby improving the heat dissipation performance of the transistor.

The embodiments of the present disclosure are described above. However, these embodiments are only for the purpose of illustration, and are not intended to limit the scope of the present disclosure. The scope of the present disclosure is defined by the appended claims and the equivalents thereof. Without departing from the scope of the present disclosure, various substitutions and modifications may be made by those skilled in the art, and these substitutions and modifications should all fall within the scope of the present disclosure.

What is claimed is:

1. A nanosheet gate-all-around transistor, comprising:
a substrate having a shallow trench isolation structure on a surface of the substrate;
a nanosheet stacking portion provided above the substrate, wherein the nanosheet stacking portion comprises a stack formed by a plurality of nanosheets, the stack formed by the nanosheets constitutes a plurality of conductive channels, and the nanosheets are graphene nanosheets;
a gate-all-around surrounding the nanosheet stacking portion; and
a source/drain region located on two opposite sides of the nanosheet stacking portion, wherein a spacer is provided between the source/drain region and the gate-all-around.

2. The nanosheet gate-all-around transistor according to claim 1, wherein the substrate is a silicon carbide substrate.

3. A method of manufacturing a nanosheet gate-all-around transistor, comprising:
providing a substrate;
forming a silicon layer, comprising: forming the silicon layer on a surface of the substrate;
forming a graphene layer, comprising: forming a silicon carbide layer on the silicon layer, and evaporating a silicon atom in the silicon carbide layer by using a thermal decomposition method, so as to form the graphene layer;
repeating the forming a silicon layer and the forming a graphene layer, so as to form a stack in which the silicon layer and the graphene layer are alternately stacked;
etching the stack and the substrate with a partial thickness to form a fin;
forming a first dielectric layer on the substrate as a shallow trench isolation layer between fins;
forming a dummy gate on the fin, and forming a first spacer on a sidewall of the dummy gate;
etching the stack in the fin, so as to release a trench for forming a source/drain;
forming a second spacer on a sidewall of the stack in the fin;
epitaxially growing a semiconductor material in the trench, so as to form the source/drain;
removing the dummy gate;
etching off the silicon layer in the stack, so as to release a nanosheet channel, wherein a stack formed by the nanosheets constitutes a plurality of conductive channels; and
forming a gate-all-around to surround the stack formed by the nanosheets.

4. The method according to claim 3, wherein the substrate is a silicon carbide substrate.

5. The method according to claim 3, wherein a heating temperature of the thermal decomposition method is in a range of 1200° C. to 1400° C.

6. The method according to claim 5, wherein the heating temperature of the thermal decomposition method is in a range of 1300° C. to 1400° C.

7. The method according to claim 3, wherein the silicon layer in the stack is etched off by using a TMAH solution.

8. The method according to claim 3, wherein the first spacer is made of silicon nitride, and/or the second spacer is made of silicon nitride.

9. The method according to claim 3, wherein the silicon layer is formed by using a molecular beam epitaxy method.

10. The method according to claim 3, further comprising: after forming the gate-all-around,
depositing an interlayer dielectric and performing interconnection.
